(19) United States
(12) Patent Application Publication
(10) Pub. No.: US 2011/0287345 A1
(43) Pub. Date: Nov. 24, 2011

(54) ELECTRON BEAM DRAWING APPARATUS, ELECTRON BEAM DRAWING METHOD, SEMICONDUCTOR DEVICE MANUFACTURING MASK MANUFACTURING METHOD, AND SEMICONDUCTOR DEVICE MANUFACTURING TEMPLATE MANUFACTURING METHOD

(76) Inventor: Masato SAITO, Machida-shi (JP)

(21) Appl. No.: 13/051,935

(22) Filed: Mar. 18, 2011

(30) Foreign Application Priority Data
May 21, 2010 (JP) 2010-117597

(51) Int. Cl. G03F 1/00; G21K 5/10; G03F 7/20

(52) U.S. Cl. 430/5; 430/296; 250/492.22

(57) ABSTRACT

According to one embodiment, there is provided a electron beam drawing apparatus includes an irradiation module which irradiates a resist coated onto a substrate with a electron beam, and a control module which controls the irradiation module and which acquires the relationship between an irradiation dose of the electron beam and a positional shift amount of a pattern, acquires a reference irradiation dose of the electron beam necessary to form a pattern on the resist, acquires an allowable positional shift amount allowed for the pattern, acquires a limit irradiation dose of the electron beam corresponding to the allowable positional shift amount on the basis of the relationship, acquires a saturated irradiation dose corresponding to a saturated positional shift amount on the basis of the relationship, and controls the irradiation module so as to irradiate all the divided pattern regions with a electron beam sequentially at least once.

### CROSS-REFERENCE TO RELATED APPLICATIONS

This application is based upon and claims the benefit of priority from Japanese Patent Application No. 2010-117597, filed May 21, 2010; the entire contents of which are incorporated herein by reference.

### FIELD

Embodiments described herein relate generally to a electron beam drawing apparatus, a electron beam drawing method, a semiconductor device manufacturing mask manufacturing method, and a semiconductor device, manufacturing template manufacturing method.

### BACKGROUND

In the process for manufacturing a semiconductor device, for example, a photomask is used as a template of a semiconductor circuit pattern. The photomask pattern is formed by using a electron beam drawing apparatus (lithography system). A method of forming the pattern is as follows. First, a substrate to whose surface a resist has been coated is held on a substrate holding module (stage). Then, the substrate is irradiated with a electron beam as the stage is being moved, thereby storing energy in the resist. Thereafter, the substrate is developed, etched, and subjected to other processes, thereby forming on the substrate a pattern corresponding to the energy charged in the resist. In addition, a desired device pattern can be formed on the substrate by performing movement control of the stage and controlling beam emission in the drawing apparatus according to previously-created semiconductor device pattern data input to the drawing apparatus.

Since materials for the resist are generally nonconductors, the region irradiated with a electron beam is charged and generates an electric field in the surrounding region. Therefore, when a region near the charged region is irradiated with a electron beam, the electric field may influence the beam. When the electron beam is affected by the electric field, the irradiation position of the electron beam is deflected by the electric field. As a result, the electron beam is caused to irradiate a position deviated from the desired irradiation position. Therefore, the position of a pattern drawn (irradiated) by the electron beam deviates from the proper position, degrading the position accuracy of the pattern.

With the recent miniaturization of semiconductor devices, requirements for the positional accuracy of the pattern on the photomask have been getting more exact. For this reason, the effect of degradation of the positional accuracy of the pattern caused by the charged resist has become a problem. As described above, with the conventional electron beam drawing apparatus, it is difficult to form a desired pattern on a resist accurately.

### BRIEF DESCRIPTION OF THE DRAWINGS

FIG. 1 is a block diagram schematically showing a basic configuration of a electron beam drawing apparatus according to an embodiment;

FIG. 2 is a plan view schematically showing a basic operation of the electron beam drawing apparatus according to the embodiment;

FIG. 3 is a flowchart to explain a drawing method of the electron beam drawing apparatus according to the embodiment;

FIG. 4 is a diagram showing the relationship between the irradiation dose of a electron beam and the positional shift amount of a pattern in the embodiment;

FIG. 5 is a diagram showing the relationship between the irradiation dose of a electron beam and the positional shift amount of a pattern in the embodiment;

FIG. 6 is a diagram to explain charging on a mask in drawing a pattern in the embodiment; and

FIG. 7 is a diagram showing the relationship between the irradiation dose of a electron beam and the positional shift amount of a pattern in a modification of the embodiment.

### DETAILED DESCRIPTION

In general, according to one embodiment, there is provided a electron beam drawing apparatus comprising: an irradiation module which irradiates a resist coated onto a substrate with a electron beam; and a control module which controls the irradiation module and which acquires the relationship between an irradiation dose of the electron beam and a positional shift amount of a pattern caused by the irradiation of the electron beam, acquires a reference irradiation dose of the electron beam necessary to form a pattern on the resist, acquires an allowable positional shift amount allowed for the pattern, acquires a limit irradiation dose of the electron beam corresponding to the allowable positional shift amount on the basis of the relationship, acquires a saturated irradiation dose corresponding to a saturated positional shift amount obtained by subtracting the allowable positional shift amount from a reference positional shift amount corresponding to the reference irradiation dose on the basis of the relationship, controls the irradiation module so as to irradiate all the divided pattern regions obtained by dividing a drawing target pattern into a plurality of regions with a electron beam sequentially at least once, causes the irradiation module to irradiate the resist with the electron beam in such a manner that a dose in each of the divided pattern regions does not exceed the limit irradiation dose and until the sum of the irradiation doses in the individual divided pattern regions reaches the saturated irradiation dose, and causes the irradiation module to irradiate the resist with a electron beam at a dose corresponding to the difference between the reference irradiation dose and the sum of the irradiation doses after the sum of the irradiation doses has reached the saturated irradiation dose.

Hereinafter, the details of the embodiment will be explained with reference to the accompanying drawings.

### Embodiment

In this embodiment, a drawing method of reducing the positional sift amount of a pattern by charging up a resist will be explained.

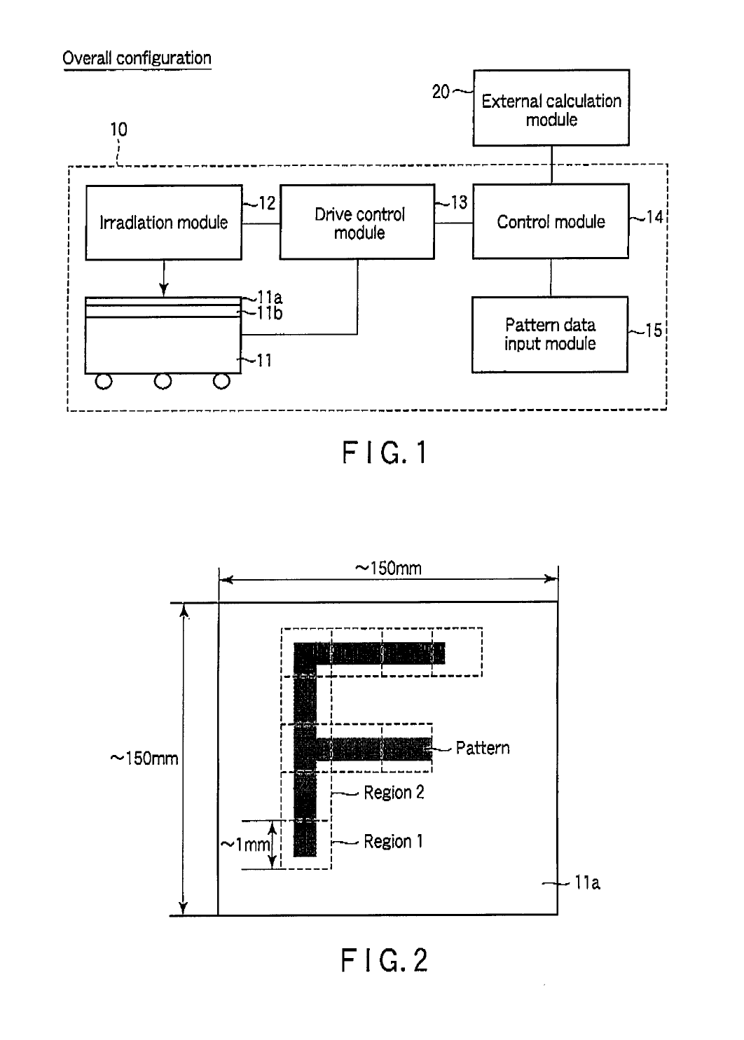

A basic configuration of a electron beam drawing apparatus according to the embodiment will be roughly explained with reference to FIG. 1. FIG. 1 is a block diagram schematically showing a basic configuration of the electron beam drawing apparatus of the embodiment.

As shown in FIG. 1, the electron beam drawing apparatus 10 comprises a substrate holding module (stage) 11 that holds a substrate 11b to which a resist 11a has been coated, an irradiation module 12 that irradiates the resist 11a with a electron beam, a drive control module 13 that drives the substrate holding module 11 and irradiation module 12, a control module 14 that controls the drive control module 13, and a pattern data input module 15 that inputs pattern data (e.g., CAD data) to the control module 14. An external calculation module 20 that carries out an operation on data and others from the control module is connected to the control module 14.

Beam irradiation position control is performed by a deflection device (not shown) incorporated in the irradiation module 12. Generally, a deflection region that can be controlled by the deflection device is smaller in size than the substrate 11b. Therefore, it is possible to draw a pattern on the whole surface of the resist 11a on the substrate 11b (or irradiate the whole surface of the resist 11a with a electron beam) by moving, for example, the substrate holding module 11.

Next, the basic operation of the electron beam drawing apparatus of the embodiment will be roughly explained with reference to FIG. 2. FIG. 2 shows a drawing operation when drawing is performed on a substrate about 150 mm square by using a drawing device that has a deflection region about 1 mm square.

As shown in FIG. 2, after the substrate holding module 11 is adjusted so that the inside of a region 1 on the resist 11a may become a region where a beam can be deflected, a pattern of the region 1 is drawn by controlling the beam irradiation position of the irradiation module (deflection device) 12. Next, the substrate holding module 11 is moved so that a region 2 adjacent to the region 1 may become a region where a beam can be deflected and a pattern existing in the region 2 is drawn by controlling the irradiation position of the irradiation module 12. These operations are repeated, thereby drawing a pattern on the whole surface of the resist 11a.

The pattern drawing method includes a step-and-repeat method and a stage-continuous-move method. In the step-and-repeat method, the substrate holding module 11 is moved to a desired drawing region and then stopped there temporarily. After a pattern has been drawn in a deflection region, the substrate holding module 11 is moved to the next desired drawing region. In the stage-continuous-move method, drawing is performed by causing the substrate holding module 11 to follow a deflection region nonstop in a tracking operation.

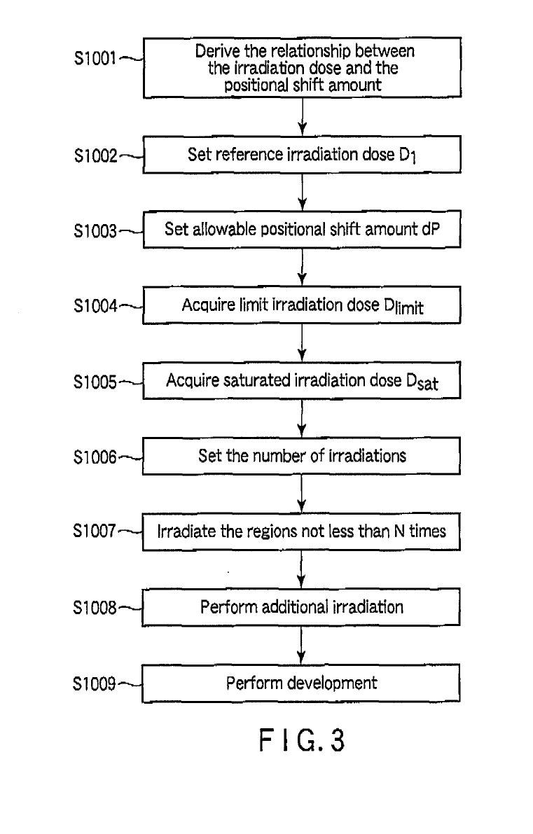

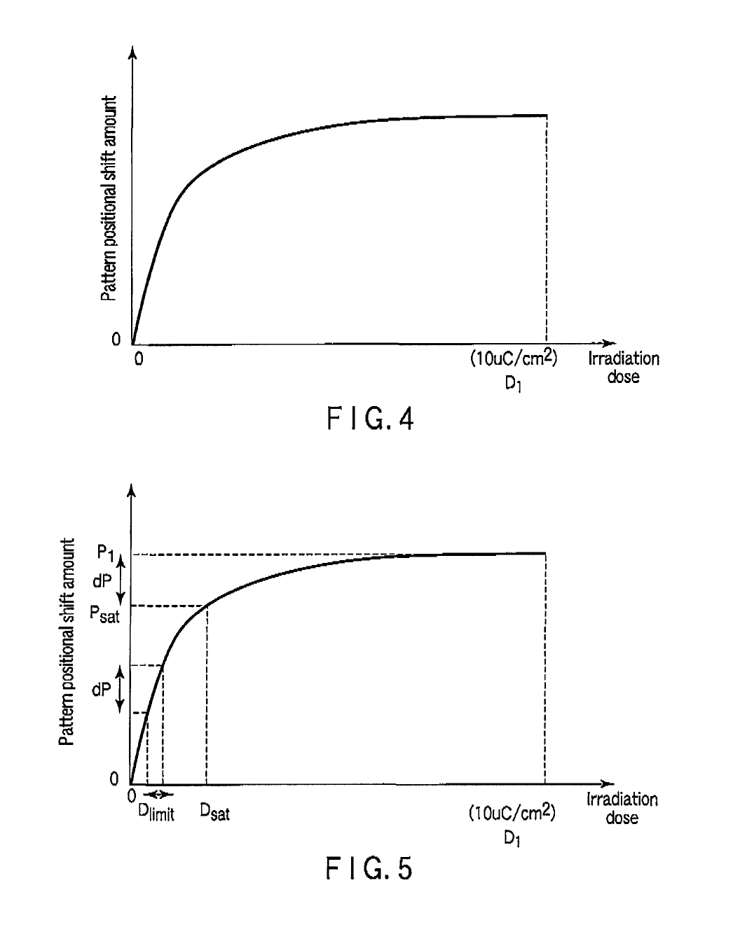

Next, a basic drawing method of the electron beam drawing apparatus according to the embodiment will be roughly explained with reference to FIGS. 3 to 5. FIG. 3 is a flowchart to explain a drawing method of the electron beam drawing apparatus according to the embodiment. FIGS. 4 and 5 are diagrams showing the relationship between the irradiation dose of a electron beam and the positional shift amount of a pattern.

In the embodiment, an explanation will be given about a case where a photomask (a mask for semiconductor manufacturing) is formed by using a resist whose charge irradiation dose D₁ necessary to form a pattern on the resist is 10 uC/cm² with a electron beam drawing apparatus whose acceleration voltage is 50 kV.

<First Step S1001>

First, the control module 14 acquires from the external calculation module 20 the relationship between the irradiation dose of a electron beam onto the resist and the positional shift amount of a pattern caused by the irradiation of the electron beam. That is, the relationship shows, for example, the relationship between the irradiation dose of a electron beam emitted to form a pattern belonging to the region 1 (the region adjacent to the region 2) shown in FIG. 2 and the positional shift amount of a electron beam generated when a electron beam is emitted to form a pattern belonging to the region 2 by an electric field caused by the irradiation dose.

A method of deriving the relationship will be explained. For example, a preparatory material obtained by coating a resist of the same type as that of the resist 11a to a substrate of the same type as that of the substrate 11b is prepared. Then, using a system equivalent to the drawing control system shown in FIG. 1, the preparatory material is irradiated experimentally with a electron beam, thereby forming a pattern. Thereafter, the relationship is derived by measuring the positional shift amount of the pattern formed on the preparatory material. Then, the relationship is stored in, for example, the external calculation module 20. FIG. 4 shows an example of the irradiation dose of a electron beam and the positional shift amount of a pattern obtained by the aforementioned method.

As seen from FIG. 4, when a specific irradiation dose has been exceeded, the positional shift of the pattern does not take place any more. The reason may be that, when a specific irradiation dose has been exceeded, the resist is not charged any more. In the example of FIG. 4, a reference irradiation dose D₁ is set near a region where the positional shift amount of the pattern begins to remain unchanged. The above relationship between the irradiation dose and the positional shift amount varies according to the material for the resist or the acceleration voltage of the electron beam.

<Second Step S1002>

Next, as shown in FIG. 4, the external calculation module 20 sets in the control module 14 the reference irradiation dose D₁ (10 uC/cm²) necessary to form a pattern on the resist. The reference irradiation dose D₁ varies according to the material for the resist.

<Third Step S1003>

Next, the pattern data input module 15 supplies information on the pattern to the control module 14. Then, on the basis of the supplied information on the pattern, the control module 14 sets an allowable positional shift amount dP, the positional shift amount allowed for a pattern formed on the substrate. The allowable positional shift amount dP may be supplied from the external calculation module 20.

<Fourth Step S1004>

Next, the external calculation module 20 derives a limit irradiation dose Dₗᵢₘᵢₜ of a electron beam corresponding to the allowable positional shift amount dP from the relationship between the irradiation dose and the positional shift amount obtained in the first step S1001.

From the relationship between the irradiation dose and the positional shift amount shown in FIG. 5, the value of the irradiation dose at which the pattern positional shift amount per unit irradiation dose is the largest is determined. In this case, the slope of the curve is the sharpest when the irradiation dose is 1 uC/cm² and, at the same time, the pattern positional shift amount per unit irradiation dose is also the largest. The minimum irradiation dose width in which the pattern positional shift amount becomes dP near the irradiation dose is the limit irradiation dose Dₗᵢₘᵢₜ. That is, the limit irradiation dose Dₗᵢₘᵢₜ is the minimum irradiation dose at which the pattern positional shift amount caused by irradiation is dP. In this example, Dₗᵢₘᵢₜ=0.5 uC/cm².

<Fifth Step S1005>

The control module 14 acquires a saturated irradiation dose Dₛₐₜ from the external calculation module 20. Specifically, as shown in FIG. 5, a value which is dP less than a reference positional shift amount P₁ of a pattern corresponding to the reference irradiation dose of D₁ necessary for pattern formation is set as a saturated positional shift amount Pₛₐₜ serving as a threshold value and an irradiation dose corresponding to the threshold value Pₛₐₜ is determined to be a saturated irradiation dose Dₛₐₜ. That is, the saturated irradiation dose Dₛₐₜ is a threshold irradiation dose. Even if a pattern is irradiated with a electron beam at a value larger than the threshold irradiation dose, the positional shift of the pattern is equal to or smaller than a preset threshold value. In this embodiment, Dₛₐₜ=2 uC/cm². The value of the saturated irradiation dose Dₛₐₜ varies according to the material for the resist, the thickness of the resist, or the structure of the drawing device near the surface of the specimen.

<Sixth Step S1006>

Next, using the derived saturated irradiation dose Dₛₐₜ and limit irradiation dose Dₗᵢₘᵢₜ, the external calculation module 20 calculates the number N of times drawing is repeated. N is an integer not less than the value of Dₛₐₜ/Dₗᵢₘᵢₜ. That is, a number equal to or larger than the value obtained by dividing the saturated irradiation dose Dₛₐₜ by the limit irradiation dose Dₗᵢₘᵢₜ is determined to be N. In this example, Dₛₐₜ/Dₗᵢₘᵢₜ=2/0.5=4 and therefore N=4.

<Seventh Step S1007>

Next, the control module 14 causes the irradiation module 12 to irradiate all the regions (divided pattern regions) obtained by dividing a desired pattern (a drawing target pattern) on the resist 11a (a F-shaped pattern in FIG. 2) into a plurality of regions with a electron beam sequentially at an irradiation dose less than the limit irradiation dose Dₗᵢₘᵢₜ. Then, the control module 14 causes the irradiation module 12 to irradiate the regions not less than N times until the sum of the irradiation doses has reached the saturated irradiation dose Dₛₐₜ.

Each irradiation dose is not necessarily constant and may be changed so as not to exceed the limit irradiation dose Dₗᵢₘᵢₜ. In addition, drawing may be done any number of times not less than N times.

<Eighth Step S1008>

In this way, after each of the regions on the resist 11a is irradiated not less than N times, the control module 14 causes the irradiation module 12 to emit a electron beam at an irradiation dose corresponding to the difference between the reference irradiation dose D₁ necessary to form a pattern and the total irradiation dose (saturated irradiation dose Dₛₐₜ) (for additional irradiation). Since irradiation has been completed to reach the saturated irradiation dose Dₛₐₜ before the eighth step S1008, the remaining irradiation dose may be used to perform drawing a plurality of times or once in the eighth step.

<Ninth Step S1009>

Next, the exposed resist 11a and substrate 11b are developed, etched, and subjected to other processes, thereby forming a desired pattern on the substrate 11b.

In this way, a photomask with the desired pattern is formed.

According to the embodiment, the electron beam drawing apparatus 10 comprises the irradiation module 12 that irradiates the resist 11a coated onto the substrate 11b with a electron beam and the control module 14 that controls the irradiation module 12. The control module 14 acquires the relationship between the irradiation dose of the electron beam (the charge amount of resist 11a) and the positional shift amount of a pattern caused by the irradiation of the electron beam (or the charging of resist 11a). The control module 14 acquires the reference irradiation dose D₁ necessary to form a pattern on the resist 11a and then the allowable positional shift amount dP for the pattern. On the basis of the relationship, the control module 14 acquires the limit irradiation dose Dₗᵢₘᵢₜ of the electron beam corresponding to the allowable positional shift amount dP and further, on the basis of relationship, acquires the saturated irradiation dose Dₛₐₜ corresponding to the saturated positional shift amount Pₛₐₜ obtained by subtracting the allowable positional shift amount dP from the reference positional shift amount P₁ corresponding to the reference irradiation dose D₁. The control module 14 controls the irradiation module 12 to irradiate all the divided pattern regions obtained by dividing a drawing target pattern into a plurality of regions with a electron beam sequentially at least once so as to cause the irradiation module 12 to irradiate the resist 11a with the electron beam in such a manner that a dose in each of the divided pattern regions does not exceed the limit irradiation dose Dₗᵢₘᵢₜ and until the sum of the irradiation doses in the individual divided pattern regions reaches the saturated irradiation dose Dₛₐₜ. After the sum of the irradiation doses has reached the saturated irradiation dose Dₛₐₜ, the control module 14 causes the irradiation module 12 to irradiate the resist 11a with a electron beam at a dose corresponding to the difference between the reference irradiation dose D₁ and the sum of the irradiation doses.

That is, a first drawing is performed on the individual regions of the resist 11a at the limit irradiation dose Dₗᵢₘᵢₜ at which the positional shift amount of the pattern is always not more than the allowable positional shift amount dP. The drawing is repeated until the saturated irradiation dose Dₛₐₜ is reached. By doing this, the positional shift amount of the pattern caused by an electric field in a region adjacent to the region where drawing is done is always not more than the allowable positional shift amount dP in each drawing. Therefore, the positional shift amount of the pattern drawn on the resist 11a is dP at a maximum. Accordingly, the difference in charge amount between adjacent regions can be always made small. As a result, the resist 11a is developed to suppress the positional shift amount of the pattern, making it possible to form a photomask with good pattern positional accuracy. This makes it possible to obtain a electron beam apparatus capable of forming a desired pattern on a resist accurately.

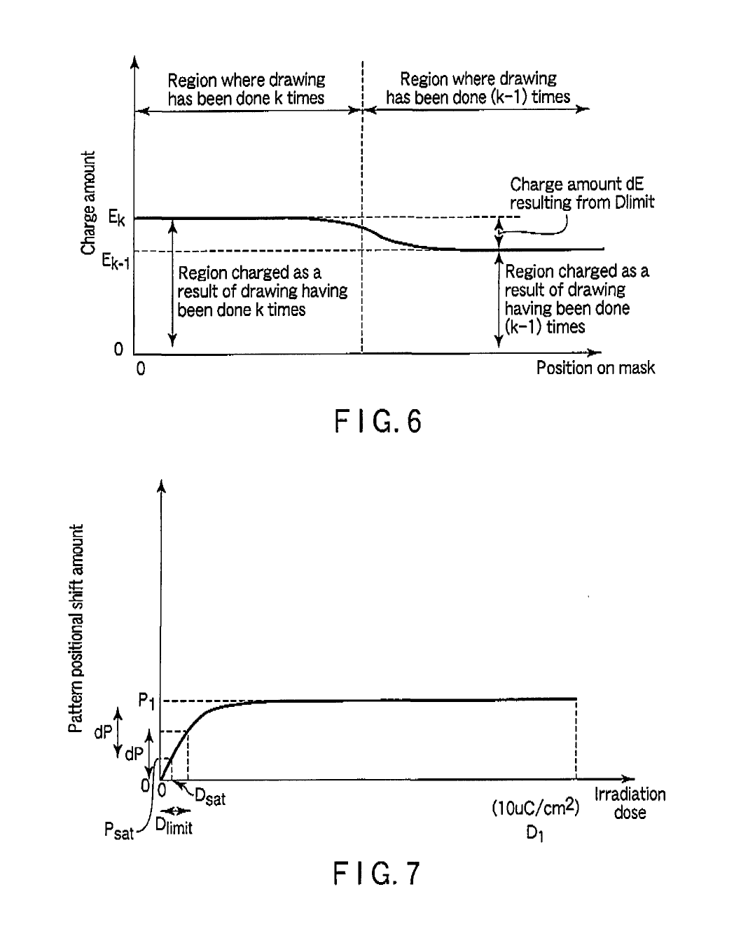

Charging on the mask in drawing a pattern will be explained more specifically with reference to FIG. 6. In this case, suppose a region where drawing has been done k times and a region where drawing has been done (k−1) times when a k-th drawing is performed.

As shown in FIG. 6, for example, when a k-th drawing is performed, a region where drawing has been done k times is charged with a charge amount Eₖ and a region where drawing has been done (k−1) times is charged with a charge amount Eₖ−1. The charge amount that influences a electron beam when a k-th drawing is performed on a region where drawing has been done (k−1) times is a charge amount dE (=Eₖ−Eₖ₋₁). That is, the difference in charge amount between the k-th drawing part and the (k−1)-th drawing part is always suppressed to an amount not more than the irradiation dose determined by Dₗᵢₘᵢₜ. Accordingly, when a k-th drawing is performed on a region where drawing has been done (k−1) times, a electron beam is influenced only by an electric field caused by the charge amount dE and therefore the shift of the pattern is suppressed to not more than the allowable positional shift amount dP.

(Modification)

Next, a basic drawing method of the electron beam drawing apparatus according to a modification of the embodiment will be roughly explained with reference to FIG. 7. FIG. 7 is a diagram showing the relationship between the irradiation dose of a electron beam and the positional shift amount of a pattern. Hereinafter, an explanation of the parts overlapping with the embodiment will be omitted.

The modification of the embodiment differs from the embodiment in that the number N of irradiations is one.

As shown in FIG. 7, in the fourth step S1004, a limit irradiation dose Dₗᵢₘᵢₜ, the minimum irradiation dose, at which the positional shift amount of a pattern becomes the allowable positional shift amount dP is derived near a place where the positional shift amount of the pattern per unit irradiation dose becomes the largest.

Then, in the fifth step S1005, a value which is the allowable positional shift amount dP smaller than the reference positional shift amount P₁ of the pattern corresponding to the reference irradiation dose D₁ necessary for pattern formation is set as a threshold value Pₛₐₜ and an irradiation dose corresponding to the threshold value Pₛₐₜ is set as a saturated irradiation dose Dₛₐₜ.

Thereafter, in the sixth step S1006, the number N of times drawing is repeated is calculated. N is an integer not less than Dₛₐₜ/Dₗᵢₘᵢₜ. Since Dₗᵢₘᵢₜ is larger than Dₛₐₜ in the modification, N=1 is set.

Then, in the seventh step S1007, the whole surface of a desired pattern is drawn only once at a dose not more than the limit irradiation dose Dₗᵢₘᵢₜ.

Furthermore, in the eighth step S1008, a electron beam is emitted at an irradiation dose corresponding to the difference between the reference irradiation dose D₁ and the irradiation dose irradiated in the seventh step S1007. In the seventh step S1007, the whole surface of the desired pattern is irradiated at not more than the limit irradiation dose Dₗᵢₘᵢₜ until the saturated irradiation dose Dₛₐₜ is reached. Therefore, in an additional irradiation, the positional shift amount of the pattern caused by the charged resist is suppressed. As a result, in the eighth step S1008, there is no need to particularly control the irradiation dose. The remaining irradiation dose may be used to perform drawing a plurality of times or once.

Then, in the ninth step S1009, the exposed substrate is developed, etched, and subjected to other processes, thereby forming a desired pattern on the resist 11a and substrate 11b.

As in the embodiment, in the modification, drawing is performed at an irradiation dose not more than the limit irradiation dose Dₗᵢₘᵢₜ corresponding to the allowable positional shift amount dP. Therefore, as in the embodiment, the positional shift amount of the pattern is suppressed, making it possible to form a photomask with good pattern position accuracy. This makes it possible to obtain a electron beam drawing apparatus capable of forming a desired pattern on a resist accurately.

While a basic drawing method has been explained in each of the embodiment and modification, for example, steps S1001 to S1003 are not limited to this order. Similarly, the order of steps S1004 and step S1005 may be changed.

In addition, while in the embodiment and modification, the explanation has been given taking a photomask manufacturing method as an example, the embodiments may be coated to the manufacture of a reflective mask (semiconductor manufacturing mask) used to form a pattern using extreme ultraviolet rays or the manufacture of a template mask (semiconductor manufacturing template) used in nanoimprint lithography.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A electron beam drawing apparatus comprising:
an irradiation module which irradiates a resist coated onto a substrate with a electron beam; and
a control module which controls the irradiation module and which
acquires the relationship between an irradiation dose of the electron beam and a positional shift amount of a pattern caused by the irradiation of the electron beam,
acquires a reference irradiation dose of the electron beam necessary to form a pattern on the resist,
acquires an allowable positional shift amount allowed for the pattern,
acquires a limit irradiation dose of the electron beam corresponding to the allowable positional shift amount on the basis of the relationship,
acquires a saturated irradiation dose corresponding to a saturated positional shift amount obtained by subtracting the allowable positional shift amount from a reference positional shift amount corresponding to the reference irradiation dose on the basis of the relationship,
controls the irradiation module so as to irradiate all the divided pattern regions obtained by dividing a drawing target pattern into a plurality of regions with a electron beam sequentially at least once,
causes the irradiation module to irradiate the resist with the electron beam in such a manner that a dose in each of the divided pattern regions does not exceed the limit irradiation dose and until the sum of the irradiation doses in the individual divided pattern regions reaches the saturated irradiation dose, and
causes the irradiation module to irradiate the resist with a electron beam at a dose corresponding to the difference between the reference irradiation dose and the sum of the irradiation doses after the sum of the irradiation doses has reached the saturated irradiation dose.

2. The electron beam drawing apparatus according to claim 1, wherein the control module sets the smallest one of the irradiation doses of the electron beam corresponding to the allowable positional shift amount as a limit irradiation dose on the basis of the relationship.

3. The electron beam drawing apparatus according to claim 1, wherein the control module causes the irradiation module to irradiate the resist with the electron beam the number of times not less than a value obtained by dividing the saturated irradiation dose by the limit irradiation dose when the resist is irradiated with the electron beam until the sum of the irradiation doses reaches the saturated irradiation dose.

4. The electron beam drawing apparatus according to claim 1, wherein the relationship between an irradiation dose of the electron beam to the resist and a positional shift amount of the pattern caused by the irradiation of the electron beam is derived by irradiating a resist of the same type as that of the resist with the electron beam in advance.

5. The electron beam drawing apparatus according to claim 1, further comprising a data input module which supplies data on the drawing target pattern to the control module.

6. A electron beam drawing method comprising:
acquiring the relationship between an irradiation dose of a electron beam and a positional shift amount of a pattern caused by the irradiation of the electron beam;
acquiring a reference irradiation dose of the electron beam necessary to form a pattern on a resist;
acquiring an allowable positional shift amount allowed for the pattern;
acquiring a limit irradiation dose of the electron beam corresponding to the allowable positional shift amount on the basis of the relationship;
acquiring a reference positional shift amount corresponding to the reference irradiation dose on the basis of the relationship;
acquiring a saturated positional shift amount obtained by subtracting the allowable positional shift amount from the reference positional shift amount on the basis of the relationship;
acquiring a saturated irradiation dose corresponding to the saturated positional shift amount on the basis of the relationship,
performing setting so as to irradiate all the divided pattern regions obtained by dividing a drawing target pattern into a plurality of regions with a electron beam sequentially at least once;
irradiating the resist with the electron beam in such a manner that a dose in each of the divided pattern regions does not exceed the limit irradiation dose and until the sum of the irradiation doses in the individual divided pattern regions reaches the saturated irradiation dose; and
irradiating the resist with a electron beam at a dose corresponding to the difference between the reference irradiation dose and the sum of the irradiation doses after the sum of the irradiation doses has reached the saturated irradiation dose.

7. The electron beam drawing method according to claim 6, wherein the limit irradiation dose is the smallest one of the irradiation doses of the electron beam corresponding to the allowable positional shift amount on the basis of the relationship.

8. The electron beam drawing method according to claim 6, wherein the irradiating the resist with the electron beam until the sum of the irradiation doses reaches the saturated irradiation dose further includes irradiating the resist with the electron beam the number of times not less than a value obtained by dividing the saturated irradiation dose by the limit irradiation dose.

9. The electron beam drawing method according to claim 6, wherein the relationship between an irradiation dose of the electron beam to the resist and a positional shift amount of the pattern caused by the irradiation of the electron beam is derived by irradiating a resist of the same type as that of the resist with the electron beam in advance.

10. The electron beam drawing method according to claim 6, further comprising: acquiring the drawing target pattern to derive the divided pattern regions.

11. A semiconductor device manufacturing mask manufacturing method comprising:
acquiring the relationship between an irradiation dose of a electron beam and a positional shift amount of a pattern caused by the irradiation of the electron beam;
acquiring a reference irradiation dose of the electron beam necessary to form a pattern on a resist;
acquiring an allowable positional shift amount allowed for the pattern;
acquiring a limit irradiation dose of the electron beam corresponding to the allowable positional shift amount on the basis of the relationship;
acquiring a reference positional shift amount corresponding to the reference irradiation dose on the basis of the relationship;
acquiring a saturated positional shift amount obtained by subtracting the allowable positional shift amount from the reference positional shift amount on the basis of the relationship;
acquiring a saturated irradiation dose corresponding to the saturated positional shift amount on the basis of the relationship,
performing setting so as to irradiate all the divided pattern regions obtained by dividing a drawing target pattern into a plurality of regions with a electron beam sequentially at least once;
irradiating the resist with the electron beam in such a manner that a dose in each of the divided pattern regions does not exceed the limit irradiation dose and until the sum of the irradiation doses in the individual divided pattern regions reaches the saturated irradiation dose;
irradiating the resist with a electron beam at a dose corresponding to the difference between the reference irradiation dose and the sum of the irradiation doses after the sum of the irradiation doses has reached the saturated irradiation dose; and
developing the resist irradiated with the electron beam.

12. A semiconductor device manufacturing template manufacturing method comprising:
acquiring the relationship between an irradiation dose of a electron beam and a positional shift amount of a pattern caused by the irradiation of the electron beam;
acquiring a reference irradiation dose of the electron beam necessary to form a pattern on a resist;
acquiring an allowable positional shift amount allowed for the pattern;
acquiring a limit irradiation dose of the electron beam corresponding to the allowable positional shift amount on the basis of the relationship;
acquiring a reference positional shift amount corresponding to the reference irradiation dose on the basis of the relationship;
acquiring a saturated positional shift amount obtained by subtracting the allowable positional shift amount from the reference positional shift amount on the basis of the relationship;
acquiring a saturated irradiation dose corresponding to the saturated positional shift amount on the basis of the relationship,
performing setting so as to irradiate all the divided pattern regions obtained by dividing a drawing target pattern into a plurality of regions with a electron beam sequentially at least once;
irradiating the resist with the electron beam in such a manner that a dose in each of the divided pattern regions does not exceed the limit irradiation dose and until the sum of the irradiation doses in the individual divided pattern regions reaches the saturated irradiation dose;
irradiating the resist with a electron beam at a dose corresponding to the difference between the reference irradiation dose and the sum of the irradiation doses after the sum of the irradiation doses has reached the saturated irradiation dose; and
developing the resist irradiated with the electron beam.
